(19) United States
(12) Patent Application Publication
(10) Pub. No.: US 2018/0272462 A1
(43) Pub. Date: Sep. 27, 2018

(54) SUPERCONDUCTING WIRE JOINING METHOD

(71) Applicant: TORAY ENGINEERING CO., LTD., Chuo-ku, Tokyo (JP)

(72) Inventor: Masaki MORI, Otsu-shi, Shiga (JP)

(21) Appl. No.: 15/757,156

(22) PCT Filed: Sep. 8, 2016
(86) PCT No.: PCT/JP2016/076371

§ 371 Date: Mar. 2, 2018

(30) Foreign Application Priority Data
Sep. 10, 2015 (JP) 2015-178672

(51) Int. Cl. B23K 20/10; H01R 4/68; H01L 39/02; B21F 15/02

(52) U.S. Cl. CPC B23K 20/103; H01R 4/68; B23K 2201/32; B21F 15/02; H01L 39/02

(57) ABSTRACT

A superconducting wire joining method joins superconducting wires each having a superconducting layer and a stabilizing layer that contacts with the superconducting layer to cover the superconducting layer. The superconducting wire joining method includes overlapping the superconducting wires such that the stabilizing layers of the superconducting wires face each other, and performing ultrasonic joining relative to overlapped portions of the superconducting wires. The overlapping of the superconducting wires and the performing of the ultrasonic joining are performed at room temperature.

This application is a U.S. National stage of International Application No. PCT/JP2016/076371 filed on Sep. 8, 2016. This application claims priority to Japanese Patent Application No. 2015-178672 filed with Japan Patent Office on Sep. 10, 2015. The entire disclosure of Japanese Patent Application No. 2015-178672 is hereby incorporated herein by reference.

### BACKGROUND

### Field of the Invention

The present invention relates to a superconducting wire joining method in which superconducting wires covered with a stabilizing film are joined, with minimal deterioration in the superconducting characteristics.

### Background Information

A characteristic of a superconductor is that its electrical resistance drops to zero under low-temperature conditions, such as at the temperature of liquid nitrogen (−196° C.), and superconductors are used in a wide range of fields such as large-scale accelerators and maglev cars.

A superconducting wire having such a superconductor has the structure shown in FIG. 2, for example, in which a superconducting layer 12 composed of a superconductor is formed on a substrate 11, and a stabilizing layer 13 composed of a good conductor such as silver covers this superconducting layer 12.

Meanwhile, it is difficult to manufacture such superconducting wires in a long length while still maintaining stable quality, so when a long superconducting wire is required, short superconducting wires are spliced together to form a long superconducting wire. However, with a typical splicing method such as soldering, the electrical resistance increases at the joints, so even if superconducting wires are spliced by such a method, the superconducting characteristics of the spliced wire suffer markedly.

As a method for splicing superconducting wires which does not diminish the superconducting characteristics after splicing, a method involving direct joining has been proposed, in which thermal energy and pressure are applied to the joint faces of superconducting wires, as described in Japanese Patent Application Publication No. 2007-012582.

### SUMMARY

However, when superconducting wires are joined by the above method, a problem is that production costs are high and the method is inefficient. More specifically, when superconducting wires are brought to a high temperature (such as 300° C.) in the joining of superconducting wires to each other by thermal energy, there is a risk that oxygen escaping from the superconducting layer will diminish the superconducting characteristics. In order to prevent this, the joining of the superconducting wires must be carried out in an oxidizing atmosphere, but preparing such an environment is expensive, and a large-scale joining device is required.

The present invention was conceived in light of the above problem, and it is an object thereof to provide a superconducting wire joining method with which superconducting wires can be joined together with a minimum amount of deterioration in the superconducting characteristics.

To solve the above problem, the superconducting wire joining method of the present invention is a method for joining superconducting wires in which a superconducting layer is covered with a stabilizing layer, said method comprising an overlapping step of overlapping two superconducting wires so that the stabilizing layers in contact with the respective superconducting layers face each other, and a joining step of ultrasonically joining overlapped portions of the two superconducting wires, wherein the overlapping step and the joining step are performed at room temperature.

With the above superconducting wire joining method, since overlapping and joining are performed at room temperature, oxygen does not escape from the superconducting layer, and the superconducting wires can be joined simply and with a minimum amount of deterioration of the superconducting characteristics.

Also, ultrasonic joining may be performed at a plurality of locations of the overlapped portions in the joining step.

The result of this is that the individual joints cover a narrower range, which makes it easier to adjust so that the entire faces of the horn and anvil of the ultrasonic joining device will be securely in contact with the superconducting wires in the joining range when each joint is made. As a result, secure joining can be performed with less likelihood that there will be any unjoined portions within the joining range, and a spliced wire having high superconducting characteristics can be obtained.

Also, it is preferable if the horn used for ultrasonic joining is in the shape of a disk, and ultrasonic joining is performed while rolling the horn against the overlapped portions in the joining step.

The result of this is that the contact surface area between the horn and the superconducting wire is smaller, which means that secure joining can be performed with less likelihood that there will be any unjoined portions within the joining range, and a spliced wire having high superconducting characteristics can be obtained. Also, performing ultrasonic joining while rolling the horn allows secure joining to be performed continuously.

With the superconducting wire joining method of the present invention, it is possible to join the superconducting wires to each other with minimal deterioration of their superconducting characteristics.

### BRIEF DESCRIPTION OF THE DRAWINGS

FIG. 1 is a simplified diagram of a joining device for performing a superconducting wire joining method in an embodiment of the present invention;

FIG. 2 is a simplified diagram of a superconducting wire in this embodiment;

FIG. 3 is a simplified diagram of the mode of splicing superconducting wires in this embodiment;

FIG. 4 is a simplified diagram of the superconducting wire joining method in this embodiment;

FIG. 5 is a simplified diagram of a superconducting wire joining method in another embodiment;

FIG. 6 is a simplified diagram of a superconducting wire joining method in another embodiment;

FIGS. 7A and 7B are cross sectional photographs of joined superconducting wires;

FIGS. 8A, 8B and 8C are simplified diagrams of the state when a joint is formed on a superconducting wire; and

FIGS. 9A, 9B and 9C are simplified diagrams of the joining device in an embodiment of the present invention.

### DETAILED DESCRIPTION OF EMBODIMENTS

An embodiment pertaining to the present invention will be described through reference to the drawings.

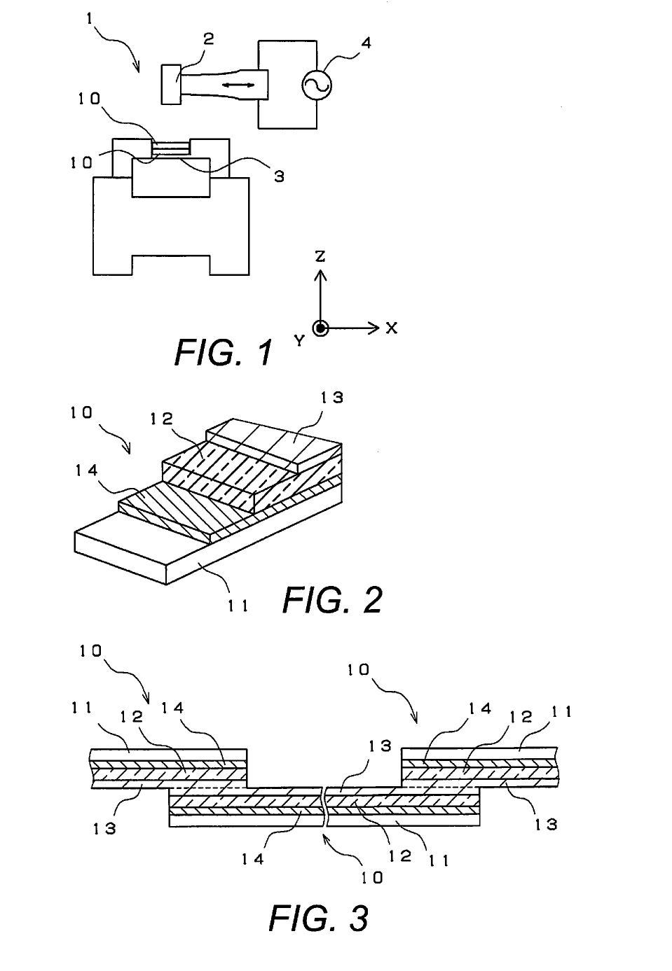

FIG. 1 is a simplified diagram of a joining device for performing a superconducting wire joining method in an embodiment of the present invention.

A joining device 1 comprises a horn 2 and an anvil 3, and joins two superconducting wires 10 by ultrasonic joining.

The horn 2 is a metal block to which an oscillator 4 is connected, and the horn 2 is ultrasonically vibrated at a specific amplitude and frequency in the horizontal direction (the arrow direction in the drawing (X axis direction)) by the operation of the oscillator 4. Also, the horn 2 can be moved in the vertical direction (Z axis direction) by a drive device (not shown), and can press from above on the superconducting wires 10 installed on the anvil 3.

The anvil 3 is a table that positions and holds the two superconducting wires 10 to be joined, so as to overlap each other, and keeps the vibration energy from the horn 2 from escaping while ultrasonic joining is being performed.

The principle of ultrasonic joining by the joining device 1 is as follows.

Joining is performed by imparting a pressing force in the vertical direction (Z axis direction) from the horn 2 to the superconducting wires 10 overlapped on the anvil 3, while applying ultrasonic vibration parallel to the joining faces of the superconducting wires 10. Consequently, the joining faces rub against each other under this ultrasonic vibration, and any oxidation film and adherents (soiling) present on the joining faces are broken up and removed, exposing clean metal faces. Consequently, an attractive force is exerted between the metal atoms of the two joining faces, further pressing increases the contact surface area of the joining faces, and joining is accomplished in a solid phase state.

FIG. 2 is a simplified diagram of a superconducting wire in this embodiment.

In this embodiment, the superconducting wire 10 is a yttrium-based (Y-based) superconducting wire, in which a superconducting layer 12 composed of a yttrium-based superconductor (YBa₂Cu₃O₇) or the like is formed on a substrate 11 composed of Hastelloy or another nickel alloy or the like.

The surface of the superconducting layer 12 is covered with a stabilizing layer 13 composed of a good conductor such as silver or Ag—Cu. The purpose of this stabilizing layer 13 is to divert electrical current to the stabilizing layer 13 in the unlikely event that resistance is produced through the loss of the superconducting state in a part of the superconducting layer 12 due to the movement of the superconducting wires 10, magnetic field fluctuation, or the like, which prevents the superconducting state from being lost in the entire superconducting layer 12.

An intermediate layer 14 is formed between the substrate 11 and the superconducting layer 12 to prevent reaction between the substrate 11 and the superconducting layer 12 and to prevent deterioration of the superconducting characteristics of the superconducting layer 12.

Here, it is difficult to produce the superconducting wire 10 having the above configuration in a long length all at once, which means that a long wire has to be made by splicing shorter superconducting wires 10.

FIG. 3 is a simplified diagram of the mode of splicing superconducting wires in this embodiment.

In the present invention, two superconducting wires 10 are overlapped so that the stabilizing layers 13 in contact with the superconducting layer 12 are facing each other (this is called the overlapping step), and the overlapped portions of the two superconducting wires 10 are ultrasonically joined (this is called the joining step), thereby splicing the superconducting wires 10 together. This splicing operation can be repeatedly performed to form a long wire.

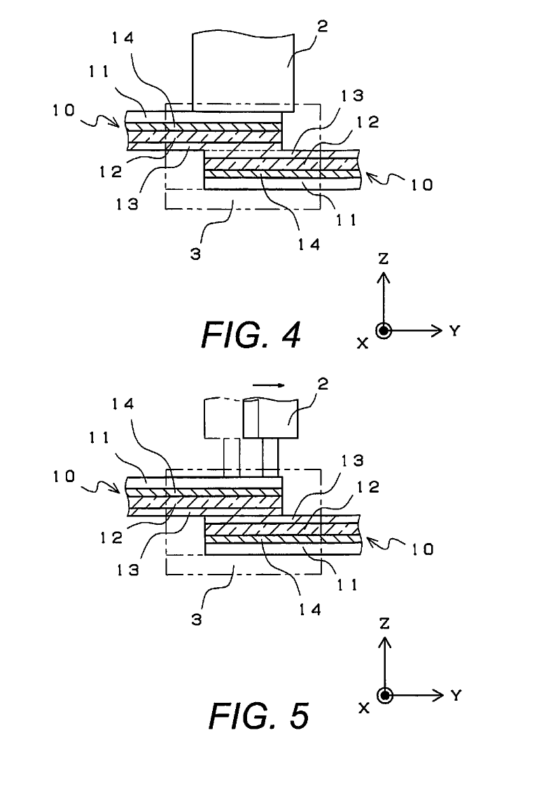

FIG. 4 is a simplified diagram of the superconducting wire joining method in this embodiment.

As described above, in this embodiment, ultrasonic joining of the two superconducting wires 10 is performed using the joining device 1. More specifically, the two superconducting wires 10 are overlapped so that the stabilizing layers 13 in contact with the superconducting layer 12 are facing each other, and the overlapping parts are held on the anvil 3, after which the horn 2 is lowered and pressed against the overlapping parts. After this, the horn 2 is ultrasonically vibrated to join the stabilizing layers 13 together.

Directly joining the stabilizing layers 13 together, that is, splicing the superconducting wires 10 without using another material such as solder, allows the superconducting wires 10 to be spliced together without substantially increasing the electrical resistance.

Also, in the present invention, the overlapping step and the joining step are performed at room temperature (about 20±20° C.). That is, no separate heating of the superconducting wires 10 is done. Consequently, there is no oxygen escape from the superconducting layer 12 due to the high temperature of the superconducting layer 12, so there is no deterioration of the superconducting characteristics of the superconducting layer 12. Therefore, there is no need to join the superconducting wires 10 in an oxidizing atmosphere, nor is it necessary to heat or cool the superconducting wires 10 during joining, so the superconducting wires 10 can be joined together very simply.

Even if the superconducting wires 10 have a temperature higher than the above-mentioned range of room temperature or a temperature lower than the above-mentioned range of room temperature because of a step performed prior to the joining of the present invention, joining may still be carried out. That is, the work involved in joining can be simplified by performing the joining directly, under room temperature conditions, without having to heat or cool the superconducting wires 10.

Next, FIG. 5 shows a superconducting wire joining method pertaining to another embodiment.

In the embodiment in FIG. 4, the size in the Y axis direction of the anvil 3 and the portion of the horn 2 in contact with the superconducting wires 10 is larger than the size of the overlapping portion of the superconducting wires 10, whereas in the embodiment in FIG. 5, the size in the Y axis direction of the portion of the horn 2 in contact with the superconducting wires 10 is smaller than the size of the overlapping portion of the superconducting wires 10. Therefore, there is a smaller range over which joining is performed by one application of ultrasonic joining, and in order to reduce the connection resistance of the joint between the superconducting wires 10, it is necessary to perform the ultrasonic joining at a plurality of locations of the overlapping portion while relatively moving the horn 2 and the anvil 3 with respect to the superconducting wires 10, such as step-feeding the horn 2 as indicated by the arrow in the drawing.

However, narrowing the range the individual joints makes it easier than in the embodiment in FIG. 4 to adjust so that the entire faces of the horn 2 and anvil 3 will be securely in contact with the superconducting wires 10 (the substrate 11) in the joining range when each joint is made. As a result, secure joining can be performed with less likelihood that there will be any unjoined portions within the joining range, and a spliced wire having high superconducting characteristics can be obtained.

In the embodiment in FIG. 5, the size of the horn 2 is reduced to reduce the size of the joint formed by one ultrasonic joining application, but the same effect can be obtained by reducing the size of the anvil 3.

In the above description, the horn 2 and the anvil 3 are moved relatively with respect to the superconducting wires 10 by moving the horn 2 or the anvil 3, but the superconducting wires 10 may be moved instead, rather than moving the horn 2 or the anvil 3. In this case, since the horn 2 and the anvil 3 can be kept parallel while performing joining a number of times, it is possible to perform the joining continuously without having to adjust the parallelism every time.

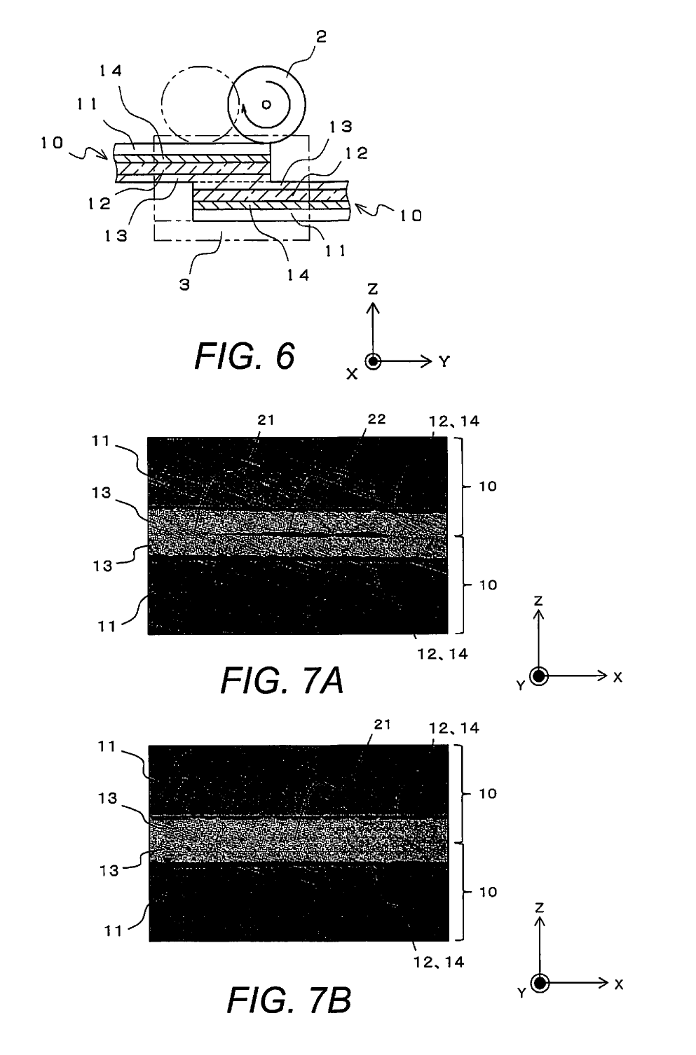

Next, a superconducting wire joining method pertaining to yet another embodiment is shown in FIG. 6.

In the embodiment in FIG. 6, the horn 2 has a disk shape, has its center axis in the X axis direction, and is able to rotate around this central axis. Consequently, the horn 2 is brought into contact with the superconducting wires 10 placed on the anvil 3, and can be rolled in the Y axis direction as indicated by the arrow in the FIG. 6 while applying pressure.

Again in this embodiment, since the contact surface area between the horn 2 and the superconducting wires 10 is small, secure joining can be performed with less likelihood that there will be any unjoined portions within the joining range, and a spliced wire having high superconducting characteristics can be obtained. By performing ultrasonic joining while rolling the horn 2 in the Y axis direction, secure joining can be performed continuously, and it is possible to form a joint that is longer in the Y axis direction and has no unjoined portions. Also, it is possible to form a joint of the desired length in the Y axis direction without retooling the horn 2 and the anvil 3.

FIGS. 7A and 7B are cross sectional photographs of superconducting wires joined by the joining method of the present invention. FIG. 7A shows the result of joining in the embodiment shown in FIG. 4, and FIG. 7B shows the result of joining in the embodiment shown in FIGS. 5 and 6. The X axis direction, Y axis direction, and Z axis direction in the drawing correspond to the orientation of the superconducting wires 10 when they have been put in the joining device 1 as shown in FIGS. 4 to 6.

Increasing the surface area of the joint is an effective way to further reduce the resistance in the spliced portion of the two superconducting wires 10. Using the horn 2 and the anvil 3 having a large size as in the embodiment of FIG. 4 makes it possible to perform joining over a wider range (the entire overlapping portion in FIG. 4) in the Y axis direction in a single ultrasonic joining application, but makes it more difficult to make an adjustment so that the entire face of the horn 2 will be in firm contact with the superconducting wires 10 (the substrate 11). There is no problem so long as the proper adjustment is made and the entire face of the horn 2 is in contact with the superconducting wires 10, but if there should be a partial gap at the contact portion between the horn 2 and the superconducting wires 10, the vibration energy from the horn 2 will not propagate to the superconducting wires 10 at this portion, and the superconducting wires 10 will not be joined together. As a result, as shown in FIG. 7A, there may be an unjoined portion 22 in addition to the joint 21 at the joining interface between the two superconducting wires 10, which can end up resulting in higher resistance at the spliced portion.

By contrast, with the embodiment in FIGS. 5 and 6, the contact surface area between the horn 2 and the superconducting wires 10 is smaller, and secure joining can be performed. Therefore, as shown in FIG. 7B, it is easier to form a joint 21 in which there is no unjoined portion 22 within the joining range.

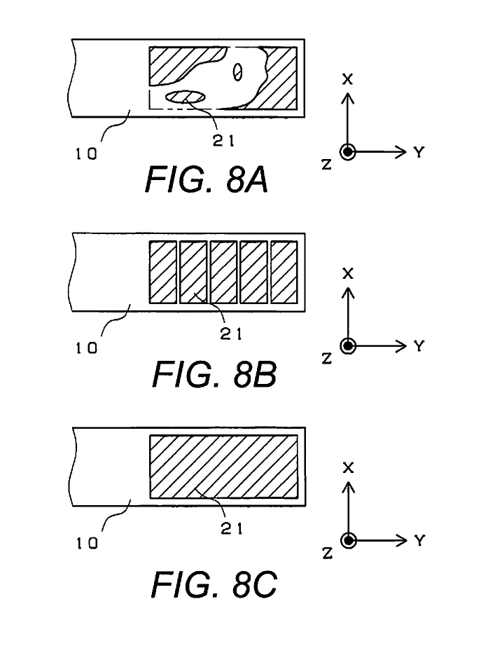

FIGS. 8A, 8B and 8C are simplified diagrams of the state when a joint is formed on a superconducting wire. FIG. 8A shows the result of joining in the embodiment shown in FIG. 4, FIG. 8B shows the result of joining in the embodiment shown in FIG. 5, and FIG. 8C shows the result of joining in the embodiment shown in FIG. 6. The X axis direction, Y axis direction, and Z axis direction in the drawing also correspond to the orientation of the superconducting wires 10 placed in the joining device 1 as shown in FIGS. 4 to 6.

The hatched portions in the views of FIGS. 8A, 8B and 8C represent the portions where the joint 21 is formed on the superconducting wire 10. With the embodiment in FIG. 4, ultrasonic joining can be performed over a wide range in a single joining operation, but the downside is that it is difficult to make an adjustment so that the horn 2 and the anvil 3 are in firm contact with the superconducting wires 10. Therefore, if the adjustment is insufficient, there is a risk that hardly any joint 21 will be formed within the joining range as shown in FIG. 8A (indicated by the chain line in the drawing), but if the joint 21 is properly adjusted, forming the joint 21 over the entire surface within the joining range as shown in FIG. 8C can be accomplished by a single ultrasonic joining operation.

Also, performing ultrasonic joining for forming a small joint 21 a plurality of times as in the embodiment shown in FIG. 5 allows the proportion of the joining range accounted for by the joint 21 to be sufficiently increased as shown in FIG. 8B.

Also, performing ultrasonic joining while rolling the horn 2 as in the embodiment shown in FIG. 6 allows the joint 21 to be formed in the desired width in the Y axis direction according to the rolling distance. The width of the joint 21 in the X axis direction is determined by the width of the portion of the horn 2 in contact with the superconducting wires 10. Consequently, as shown in FIG. 8C, a joint 21 covering a wide range can be formed within the joining range.

Next, the results of actually overlapping and joining the superconducting wires 10 in a room temperature environment will be given. At this point, the thickness of the stabilizing layer 13 of each superconducting wire 10 was about 10 μm, and the width was about 5 mm.

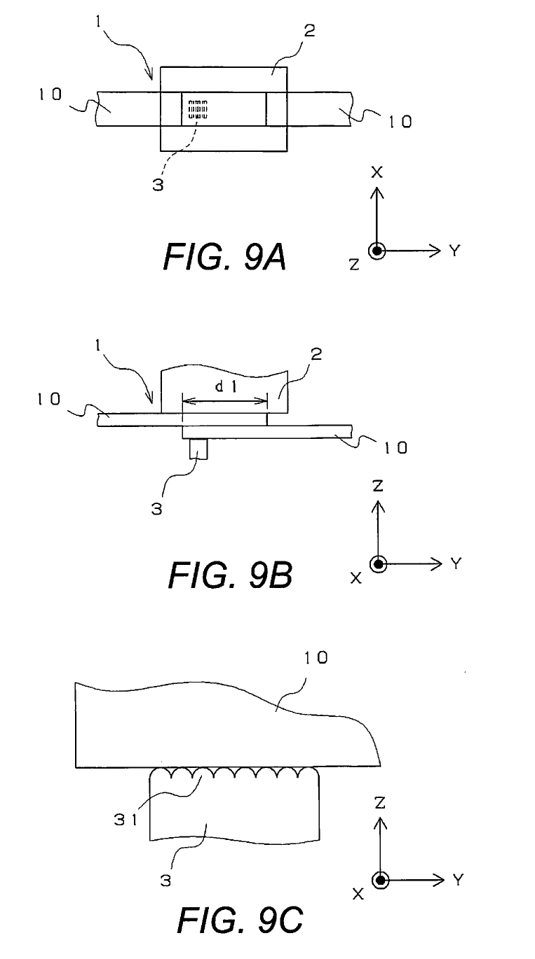

FIGS. 9A, 9B and 9C show the form of the horn 2 and the anvil 3 used here. FIG. 9A is a top view, FIG. 9B is a side view, and FIG. 9C is a detail view of the distal end portion of the anvil 3. The length of the overlapping portion of the superconducting wires 10 (the length dl in FIG. 9C) is 30 mm, the portion of the horn 2 in contact with the superconducting wires 10 is larger than this overlapping portion, and the entire overlapping portion is in contact.

As shown in FIG. 9C, the anvil 3 has a distal end shape in which semicylindrical tip portions 31 are arranged in one direction, and in this embodiment, eight semicylindrical portions with a radius of 0.25 mm are arranged at a pitch of 0.5 mm. That is, the size of the portion of the anvil 3 in contact with the superconducting wires 10 in the width direction (the Y axis direction in FIGS. 9A, 9B and 9C) is about 3.5 mm. The size in the depth direction (the X axis direction in FIGS. 9A, 9B and 9C) is 3 mm, and the portion of the anvil 3 in contact with the superconducting wires 10 is sufficiently smaller than the overlapping portion. That is, the horn 2 and the anvil 3 allow secure joining to be performed with reduced likelihood that there will be any unjoined portion in the joining range, just as in the embodiment in FIG. 5. Joining was then repeated nine times while shifting the position of the anvil 3 in the Y axis direction, and the above-mentioned overlapping portion was joined over substantially the entire Y axis direction.

Table 1 shows the results when the superconducting wires 10 were actually overlapped and joined in a room temperature environment, under several sets of conditions, using the above-mentioned horn 2 and anvil 3, and using the load during ultrasonic joining, the joining duration, and the amplitude of the horn 2 as parameters.

TABLE 1

| | | Time | Amplitude | Joining |
|---|---|---|---|---|
| No. | Load (N) | (ms) | (μm) | state |
| 1 | 600 | 150 | 30 | x |
| 2 | 600 | 150 | 45 | x |
| 3 | 600 | 300 | 45 | x |
| 4 | 1000 | 300 | 45 | x |
| 5 | 1400 | 500 | 55 | Δ |
| 6 | 1000 | 300 | 60 | ∘ |
| 7 | 1000 | 500 | 60 | ∘ |
| 8 | 1200 | 500 | 60 | ∘ |
| 9 | 1500 | 500 | 60 | x |
| 10 | 1000 | 750 | 60 | ∘ |

In the evaluation of the joining state in Table 1, the superconducting wire 10 that had been joined was taken in hand, an external force such as bending or twisting was applied several times, and a sample that separated at that point is indicated with an x. A sample that withstood the bending and twisting was cut and the size of the joint (the joint 21 shown in FIGS. 8A, 8B and 8C) was evaluated. A sample smaller than a specific size is indicated with a Δ, and a sample larger than this size is indicated with a ∘.

If the load during joining, the joining duration, and the amplitude of the horn 2 were too small, the joining was insufficient and the wires readily separated, or even if they did not readily separate, the size of the joint was not large enough, but with the production conditions for sample Nos. 6 to 8 and No. 10, sufficient joint surface area was obtained, and the resistance of these samples was only about 30 to 70 nΩ, which is low enough for use as a superconducting wire. Also, the load was too high with sample No. 9, so the stabilization layer 13 and the superconducting layer 12 were destroyed.

With the above superconducting wire joining method, it is simple to join superconducting wires to each other with minimal deterioration of their superconducting characteristics.

The superconducting wire joining method of the present invention is not limited to the embodiment described above, and other embodiments are also possible within the scope of the present invention. For instance, in the above description, the stabilizing layer was formed only on the superconducting layer, but it may also be formed on the substrate (the face on the opposite side from the face on which the intermediate layer is formed). Here again, superconducting wires can be spliced with minimal deterioration of their superconducting characteristics by performing ultrasonic joining with the stabilizing layers in contact with the superconducting layer facing each other.

1. A superconducting wire joining method for joining superconducting wires each having a superconducting layer and a stabilizing layer that contacts with the superconducting layer to a cover the superconducting layer, the superconducting wire joining method comprising:
overlapping the superconducting wires such that the stabilizing layers of the superconducting wires face each other; and
performing ultrasonic joining relative to overlapped portions of the superconducting wires,
the overlapping of the superconducting wires and the performing of the ultrasonic joining being performed at room temperature.

2. The superconducting wire joining method according to claim 1, wherein
the performing of the ultrasonic joining includes performing the ultrasonic joining at a plurality of locations of the overlapped portions.

3. The superconducting wire joining method according to claim 1, wherein
the performing of the ultrasonic joining includes performing the ultrasonic joining by using a horn with while rolling the horn against the overlapped portions.

4. The superconducting wire joining method according to claim 1, wherein
the performing of the ultrasonic joining includes performing the ultrasonic joining by using a horn relative to the overlapped portions that have been held by an anvil.

5. The superconducting wire joining method according to claim 4, wherein
dimensions of the horn and the anvil in a predetermined direction are larger than a dimension of the overlapped portions in the predetermined direction.

6. The superconducting wire joining method according to claim 4, wherein
at least one of dimensions of the horn and the anvil in a predetermined direction is smaller than a dimension of the overlapped portions in the predetermined direction.

7. The superconducting wire joining method according to claim 6, wherein
the performing of the ultrasonic joining includes performing the ultrasonic joining at a plurality of locations of the overlapped portions.

8. The superconducting wire joining method according to claim 4, wherein
the performing of the ultrasonic joining further includes performing the ultrasonic joining while relatively moving the horn with respect to the overlapped portions.

9. The superconducting wire joining method according to claim 8, wherein
the performing of the ultrasonic joining includes performing the ultrasonic joining at a plurality of locations of the overlapped portions.

10. The superconducting wire joining method according to claim 8, wherein
the horn has a shape of a disk, and
the performing of the ultrasonic joining includes performing the ultrasonic joining while rolling the horn against the overlapped portions.
